(19) United States
(12) Patent Application Publication
(10) Pub. No.: US 2016/0142077 A1
(43) Pub. Date: May 19, 2016

(54) DUAL-BAND FILTER AND OPERATING METHOD THEROF

(71) Applicant: SAMSUNG ELECTRO-MECHANICS CO., LTD., Suwon-si (KR)

(72) Inventors: Chan Yong JEONG, Suwon-si (KR); Hyun Jun LEE, Suwon-si (KR); Myeong Woo HAN, Suwon-si (KR)

(73) Assignee: SAMSUNG ELECTRO-MECHANICS CO., LTD., Suwon-si (KR)

(21) Appl. No.: 14/886,547

(22) Filed: Oct. 19, 2015

(30) Foreign Application Priority Data
Nov. 19, 2014 (KR) 10-2014-0161690

(51) Int. Cl. H04B 1/00; H03H 9/72; H03H 7/46; H03H 7/42; H03H 7/01; H03H 9/70; H03H 7/38

(52) U.S. Cl. CPC H04B 1/0057; H03H 9/706; H03H 9/725; H03H 7/38; H03H 7/42; H03H 7/0161; H03H 7/463; H04W 84/12

(57) ABSTRACT

A dual-band filter and method thereof include a diplexer configured to process one of a first band signal and a second band signal, which includes a frequency band different from a frequency band of the first band signal, and block the other of the first band signal and the second band signal. A balun is configured to convert the first band signal from a differential signal to a single signal in response to the first band signal being transmitted, and convert the first band signal from a single signal to a differential signal in response to the first band signal being received. A direct current (DC) voltage supply port configured to supply a DC voltage to the balun when the first band signal is received.

### CROSS-REFERENCE TO RELATED APPLICATION

This application claims the priority to, and benefit under 35 USC 119(a) of Korean Patent Application No. 10-2014-0161690 filed on Nov. 19, 2014, with the Korean Intellectual Property Office, the disclosure of which is incorporated herein by reference.

### BACKGROUND

1. Field

The following description relates to a dual-band filter and an operating method thereof.

2. Description of Related Art

In accordance with the development of wireless communications technologies, the ability to operate within various wireless network communications standards has been implemented in single devices. For example, in the case of Wi-Fi communications, IEEE 802.11ac wireless networking standard has been added to existing IEEE 802.11a/b/g/n families. Devices able to undertake communications using the IEEE 802.11ac standard may communicate using the 20 MHz, 40 MHz, 80 MHz and 160 MHz bands, within the 5 GHz band. Thus, a dual-band technique supporting both the existing 2.4 GHz band and the added 5 GHz band has been used.

A component having a significant effect on radio frequency (RF) performance in a Wi-Fi product is a front-end circuit including a power amplifier, a low noise amplifier, and a switch. In addition, a filter, such as a diplexer, is formed between an antenna and the front-end circuit.

Conventionally, diplexers have been used alone to simultaneously support dual-band communications by a single antenna. However, in accordance with the extension of the Long-Term Evolution (4G LTE) band, there is a need to add a bandpass filter in order to secure performance between Wi-Fi and an adjacent LTE channel. Thus, a complex filter to complement performance of the front-end circuit required is needed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a dual-band filter, including: a diplexer configured to process one of a first band signal and a second band signal, which may include a frequency band different from a frequency band of the first band signal, and block the other of the first band signal and the second band signal; a balun configured to convert the first band signal from a differential signal to a single signal in response to the first band signal being transmitted, and convert the first band signal from a single signal to a differential signal in response to the first band signal being received; and a direct current (DC) voltage supply port configured to supply a DC voltage to the balun when the first band signal is received.

The dual-band filter may also include a first signal port configured to receive or transmit the first band signal as a differential signal; a second signal port configured to receive or transmit the second band signal; and a common port configured to transmit or receive the first band signal or the second band signal to or from an antenna.

The first signal port may transmit the first band signal amplified by a complementary metal-oxide semiconductor (CMOS) power amplifier.

The first signal port may transmit and receive a first band signal, within the 2.4 GHz band, and the second signal port transmits and receives a second band signal, within the 5 GHz band, as a single signal.

The dual-band filter may also include a bandpass filter configured to filter the first band signal.

The bandpass filter may include a surface acoustic wave filter or a bulk film acoustic resonator filter.

The dual-band filter may also include a first matching network connected between the second signal port and the diplexer; a second matching network connected between the diplexer and a bandpass filter, wherein the bandpass filter is configured to filter the first band signal; and a third matching network connected between the bandpass filter and the balun.

In accordance with an embodiment, there is provided a dual-band filter, including: a common port configured to receive or transmit a first band signal or a second band signal, wherein the second band signal may include a frequency band different from a frequency band of the first band signal; a diplexer configured to process one of the first band signal and the second band signal and to block the other of the first band signal and the second band signal; a bandpass filter connected to the diplexer and configured to filter the first band signal; and a balun configured to convert the filtered first band signal from a differential signal to a single signal when the first band signal is transmitted.

The dual-band filter may also include a first signal transmitting port configured to receive the first band signal as the differential signal; a first signal receiving port configured to transmit the first band signal as the single signal; and a second signal port configured to receive or transmit the second band signal.

The diplexer is connected to the second signal port and the common port, and the balun is connected to the bandpass filter and the first signal transmitting port.

The first signal receiving port may be connected to the bandpass filter to output the first band signal as the single signal.

The first signal transmitting port may transmit the first band signal, within the 2.4 GHz band, amplified by a complementary metal-oxide semiconductor (CMOS) power amplifier, and the second signal port transmits and receives the second band signal, within the 5 GHz band, as the single signal.

The dual-band filter may also include a first matching network connected between the second signal port and the diplexer; a second matching network connected between the diplexer and the bandpass filter; and a third matching network connected between the bandpass filter and the balun, wherein the bandpass filter may include a surface acoustic wave filter or a film bulk acoustic resonator filter.

In accordance with an embodiment, there is provided a method of a dual-band filter, including: processing, using a diplexer, one of a first band signal and a second band signal, which may include a frequency band different from a frequency band of the first band signal, and blocking the other of the first band signal and the second band signal; converting, using a balun, the first band signal from a differential signal to a single signal in response to the first band signal being transmitted; converting, using the balun, the first band signal from a single signal to a differential signal in response to the first band signal being received; and supplying, using a direct current (DC) voltage supply port, a DC voltage to the balun when the first band signal is received.

The method may also include receiving or transmitting, using a first signal port, the first band signal as a differential signal; receiving or transmitting, using a second signal port, the second band signal; and transmitting or receiving, using a common port, the first band signal or the second band signal to or from an antenna.

The method may also include amplifying the first band signal using a complementary metal-oxide semiconductor (CMOS) power amplifier; and transmitting, using the first signal port, the amplified first band signal.

Other features and aspects will be apparent from the following detailed description, the drawings, and the claims.

### BRIEF DESCRIPTION OF DRAWINGS

FIGS. 1 and 2 are diagrams illustrating a dual-band filter, according to an embodiment;

FIGS. 3A through 3C are graphs illustrating attenuation of the dual-band filter;

FIGS. 4A and 4B are graphs illustrating insertion loss of the dual-band filter;

FIGS. 5A through 5D are graphs illustrating return loss of the dual-band filter;

FIG. 6 is a flow chart illustrating a method of a dual-band filter, according to an embodiment; and

FIG. 7 is a flow chart illustrating a transmission process in the method of the dual-band filter, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

It will be understood that when an element or layer is referred to as being “on” or “connected to” another element or layer, it can be directly on or connected to the other element or layer or through intervening elements or layers may be present. In contrast, when an element is referred to as being “directly on” or “directly connected to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. These terms do not necessarily imply a specific order or arrangement of the elements, components, regions, layers and/or sections. Thus, a first element, component, region, layer or section discussed below could be termed a second element, component, region, layer or section without departing from the teachings description of the present invention.

In the drawings, the shapes and dimensions of elements may be exaggerated for clarity, and the same reference numerals will be used throughout to designate the same or like elements.

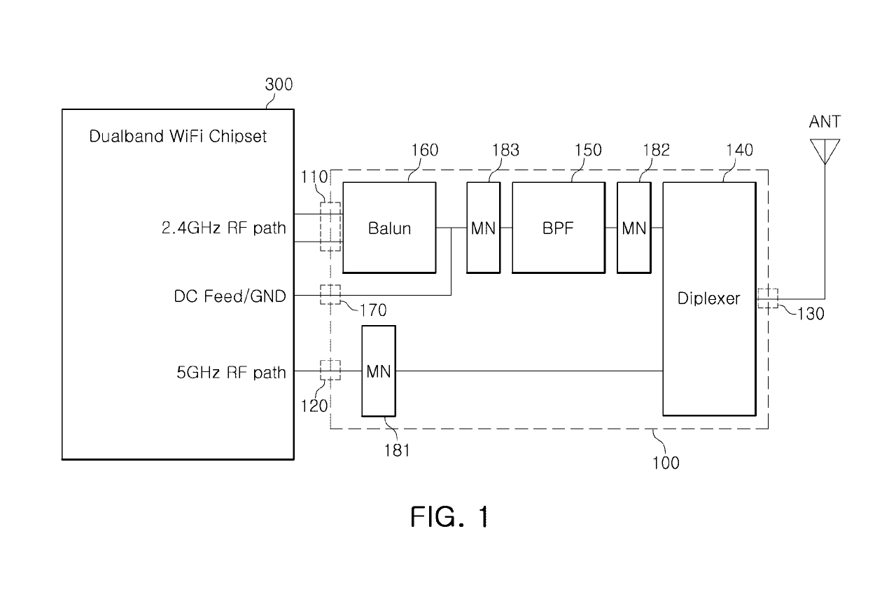

FIGS. 1 and 2 are diagrams illustrating a dual-band filter, according to an embodiment.

Referring to FIG. 1, a dual-band filter 100, according to an embodiment, includes a first signal receiving and transmitting port 110, a second signal receiving and transmitting port 120, a common port 130, a diplexer 140, a bandpass filter 150, a balun 160, a direct current (DC) voltage supply port 170, a first matching network 181, a second matching network 182, and a third matching network 183.

Referring to FIG. 2, a dual-band filter 200, according to an embodiment, includes a first signal transmitting port 211, a first signal receiving port 212, a second signal receiving and transmitting port 220, a common port 230, a diplexer 240, a bandpass filter 250, a balun 260, a direct current (DC) voltage supply port 270, a first matching network 281, a second matching network 282, and a third matching network 283.

The first signal receiving and transmitting port 110 receives or output a first band signal as a differential signal. For example, the first band signal is a signal for WiFi/BT or LTE communications, within the 2.4 GHz band.

For example, the first signal receiving and transmitting port 110 transmits the first band signal, amplified by a complementary metal-oxide-semiconductor (CMOS) power amplifier. Because the power amplifier amplifies a large signal, a large degree of energy loss may occur during an amplification process. The power amplifier may be implemented using gallium arsenide (GaAs) to improve energy efficiency, and may be implemented using the CMOS to improve costs and size. In order to complement energy efficiency of the power amplifier using the CMOS, the dual-band filter 100 includes the balun 160.

A second band signal having a frequency band different from that of the first band signal is input to or output from second signal receiving and transmitting ports 120 and 220A. For example, the second band signal is within the 5 GHz band, and is transmitted and received as a single signal. However, other frequency bands may be used and multiple signals may be transmitted and received and multiplexed as a single signal.

The common ports 130 and 230 transmit the first band signal or the second band signal to an antenna, and receive the first band signal or the second band signal from the antenna. Here, the antenna may be connected to the common ports 130 and 230.

The diplexers 140 and 240 are connected to the second signal receiving and transmitting ports 120 and 220 and the common ports 130 and 230 to conduct, process, pass-through, or receive and transmit one of the first band signal and the second band signal and block the other thereof. For example, the diplexer operates within the 2.4 GHz band in low pass filter form, and operates within the 5 GHz band in high-pass filter form or high-bandpass filter form.

The bandpass filters 150 and 250 are connected to the diplexers 140 and 240 to band-pass filter the first band signal.

In addition, the bandpass filters 150 and 250 include a surface acoustic wave filter or a film bulk acoustic resonator filter. For example, a frequency of a WiFi/BT 2.4 G band is 2402 to 2484 MHz, a frequency of band 40 of an LTE network is 2300 to 2370 MHz, a frequency of Band 7 of an LTE network is 2500 to 2690 MHz, a frequency of band 41 of an LTE network is 2496 to 2690 MHz, and a frequency of band 38 of an LTE network is 2570 to 2620 MHz. That is, the respective communications bands of the first band signal are adjacent to each other. Therefore, because bandpass filters 150 and 250 have high quality factor (QF) and include the surface acoustic wave filter or the film bulk acoustic resonator filter having excellent out of band rejection performance, several communications bands which are adjacent to each other coexist.

The baluns 160 and 260 are connected to bandpass filters 150 and 250, through the third matching network 183 and 283, respectively, and the first signal receiving and transmitting port 110 to convert the first band signal, a differential signal, to a single signal when the first band signal is transmitted and to convert the first band signal, a single signal, to a differential signal when the first band signal is received. In an alternative configuration, the baluns 160 and 250 may be directly connected to the bandpass filters 150 and 250.

In an example in which the baluns 160 and 260 are configured using a CMOS process as in the power amplifier, quality factor (QF) decreases. Therefore, the baluns 160 and 260 are included in the dual-band filters 100 and 200, so that the dual-band filters 100 and 200 are implemented at high QF. That is, the dual-band filers 100 and 200 include the baluns 160 and 260 to alleviate a design condition of the power amplifier and to be effectively implemented by the CMOS process.

The DC voltage supply port 170 is connected to the balun 160 to supply a DC voltage to the balun 160 when the first band signal is received.

Typically, a low noise amplifier receives and amplifies the first band signal. However, there is a need to resolve a decrease of energy loss when the low noise amplifier receives the first band signal. For example, when the first received band signal passes through the balun 160, the energy loss due to reception of the first band signal may occur. Therefore, to overcome such energy loss, the DC voltage supply port 170 supplies the DC voltage to the balun 160, such that the reception loss when the first band signal passes through the balun 160 is reduced.

The first matching networks 181 and 281 are connected between the second signal receiving and transmitting ports 120 and 220 and the diplexers 140 and 240. The second matching networks 182 and 282 are connected between the diplexers 140 and 240 and bandpass filters 150 and 250. The third matching networks 183 and 283 are connected between bandpass filters 150 and 250 and the balun 160 and 260, respectively.

Because signals passing through the dual-band filters 100 and 200 are microwaves, the dual-band filters 100 and 200 perform a matching such that energy loss of signals passing through is significantly reduced. Therefore, performance of the dual-band filters 100 and 200 are improved by implementing the respective structural blocks illustrated and described with respect to FIGS. 1 and 2 and by matching networks by a single dual-band filter.

The first signal transmitting port 211A receives the first band signal as the differential signal.

The first signal receiving port 212 outputs the first band signal as a single signal. That is, the dual-band filter 200 of FIG. 2 transmits and receives the first signal through paths different from each other.

In one example, the first signal receiving port 212 is connected to bandpass filter 250 to output the first band signal as the single signal. The first band signal is amplified by the low noise amplifier when received. As the first received band signal is passed to the low noise amplifier, a reduction in energy loss is desired. For example, the first band signal does not pass through the balun 260 to avoid the energy loss due to reception of the first band signal. Therefore, by extracting the first received band signal between the balun 260 and bandpass filter 250, because the first band signal does not pass through the balun 260, the energy loss is reduced.

Furthermore, the dual-band filters 100 and 200 are connected to a dual-band chipset 300. For example, the dual-band chipset 300 generates and amplifies the first signal to be output to the first signal receiving and transmitting port 110, and generates and amplifies the second signal to be output to the second signal receiving and transmitting port 210.

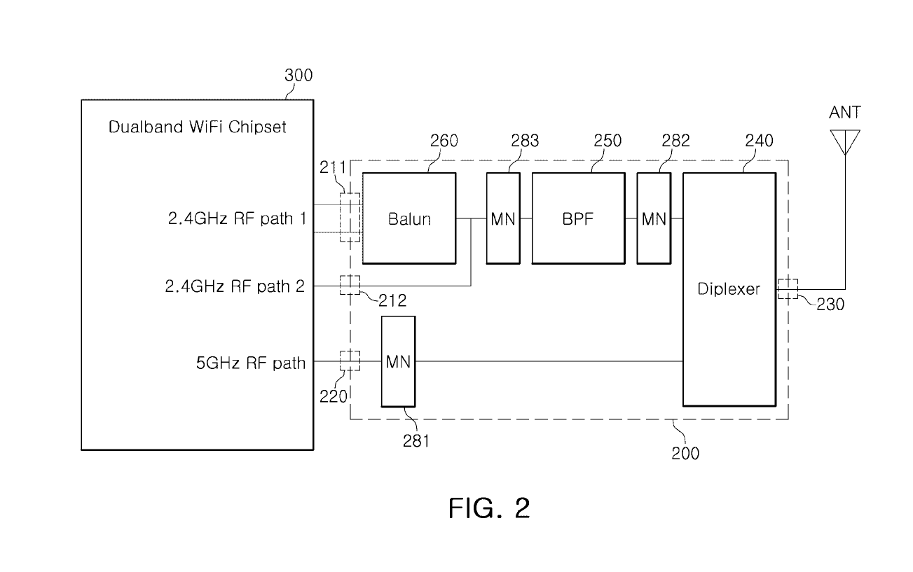

Hereinafter, graphs of FIGS. 3 through 5 are measurement graphs of the dual-band filters 100 and 200 of FIGS. 1 and 2.

FIGS. 3A through 3C are graphs illustrating attenuation of the dual-band filter.

Referring to FIG. 3A illustrates an S-parameter value between the common port and the first signal receiving and transmitting port. FIG. 3B illustrates the S-parameter value between the common port and the second signal receiving and transmitting port. FIG. 3C illustrates the S-parameter value between the first signal receiving and transmitting port and the second signal receiving and transmitting port.

Referring to FIG. 3A, a signal, except for a signal within the 2.38 GHz to 2.49 GHz band, is blocked up to about 50 dB.

Referring to FIG. 3B, a signal, except for a signal within the 4 GHz band or more, is blocked up to about 40 dB.

Referring to FIG. 3C, a signal of an entire band is blocked about 40 dB or more.

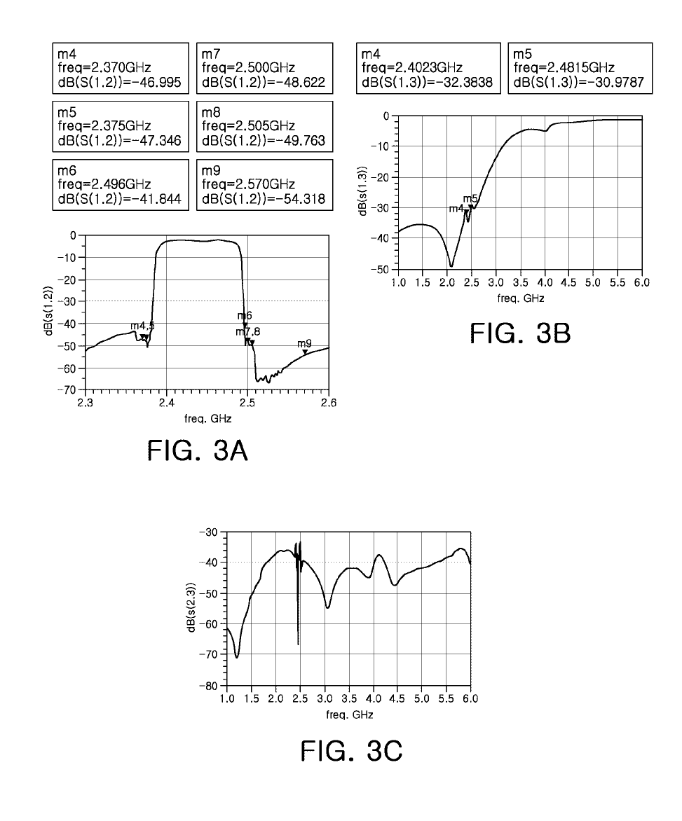

FIGS. 4A and 4B are graphs illustrating insertion loss of the dual-band filter.

FIG. 4A illustrates an S-parameter value between the common port and the first signal receiving and transmitting port. FIG. 4B illustrates the S-parameter value between the common port and the second signal receiving and transmitting port.

Referring to FIG. 4A, a signal within the 2.38 GHz to 2.49 GHz band passes while having a power loss or intensity of about 3 dB.

Referring to FIG. 4B, a signal within the band of 4 GHz or more passes, while having a power loss of about 3 dB.

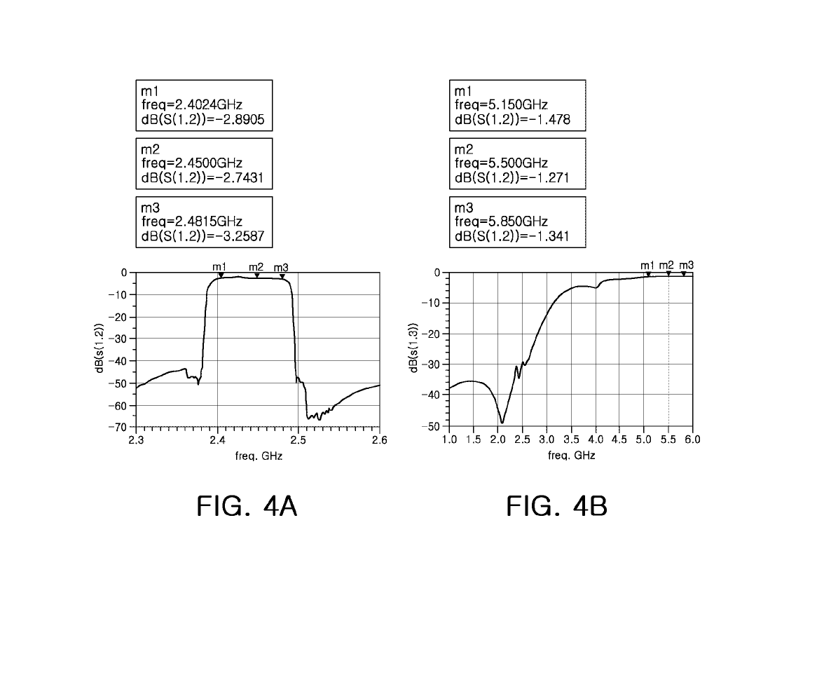

FIGS. 5A through 5D are graphs illustrating return loss of the dual-band filter.

FIG. 5A illustrates the return loss of the first signal receiving and transmitting port when a signal is transmitted and received between the common port and the first signal receiving and transmitting port. FIG. 5B illustrates the return loss of the common port when the signal is transmitted and received between the common port and the first signal receiving and transmitting port. FIG. 5C illustrates the return loss of the second signal receiving and transmitting port when the signal is transmitted and received between the common port and the second signal receiving and transmitting port. FIG. 5D illustrates the return loss of the common port when the signal is transmitted and received between the common port and the second signal receiving and transmitting port.

Referring to FIGS. 5A and 5B, a signal within the band of 2.38 GHz to 2.49 GHz have a low return power or intensity loss of −15 dB or less.

Referring to FIGS. 5C and 5D, a signal within the band of 4 GHz or more have a low return power or intensity loss of −15 dB or less.

Hereinafter, an operating method of a dual-band filter, according to an embodiment, will be described. Because the operating method of a dual-band filter, according to an embodiment, is performed by the structural elements illustrated and described in the dual-band filters 100 and 200 described above with reference to FIGS. 1 and 2, an overlapped description for contents that are the same as or correspond to the above-mentioned contents will be omitted.

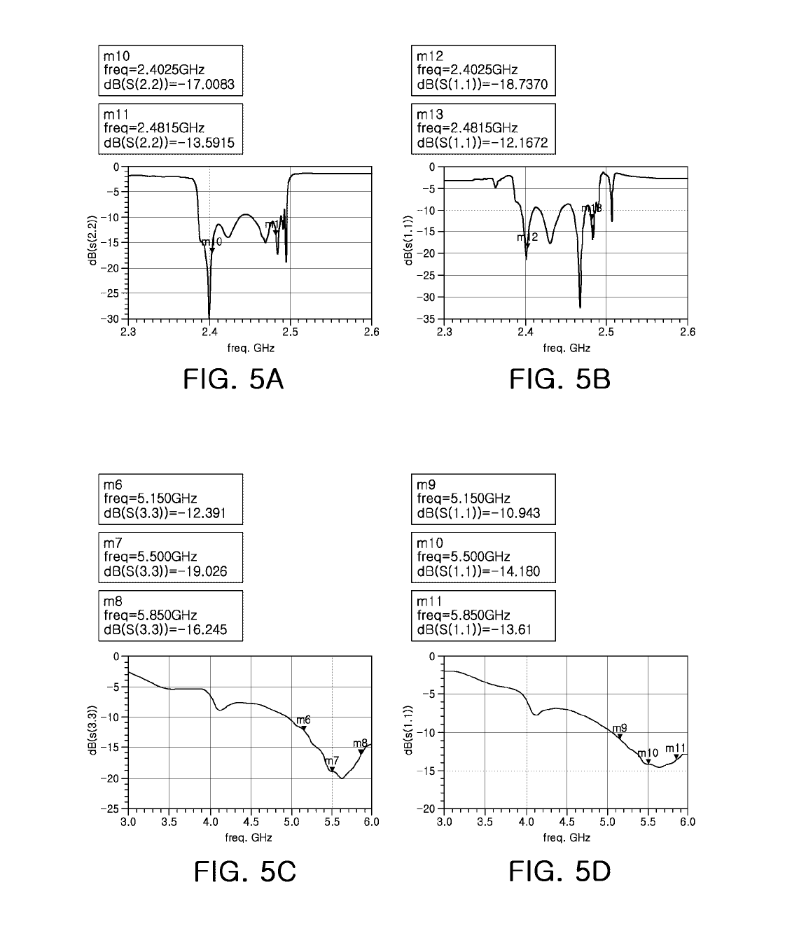

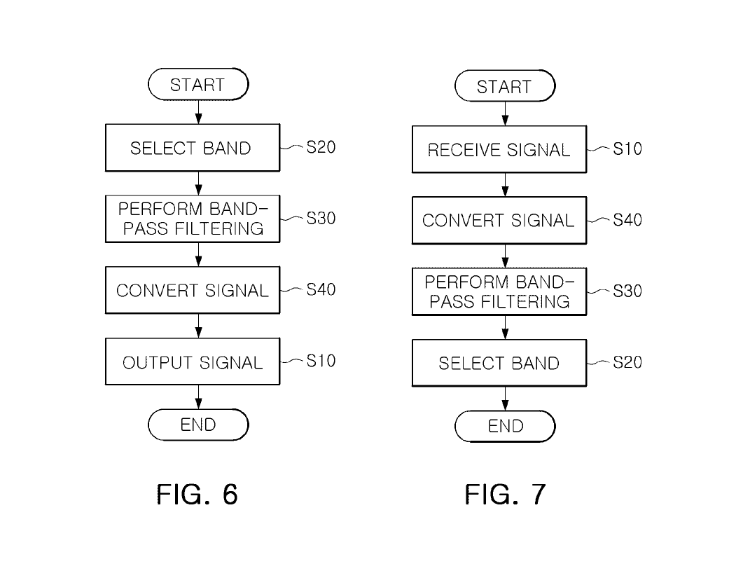

FIGS. 6 and 7 are flow charts illustrating a method of a dual-band filter, according to an embodiment.

Referring to FIGS. 6 and 7, the operating method of a dual-band filter, according to an, includes, at operation S10, a signal reception and output; at operation S20, a band selection; at operation S30, a bandpass filtering; and at operation S40, a signal conversion.

At the signal reception and output operation S10, the dual-band filter receives or transmits a first band signal and a second band signal, having a frequency band different from that of the first band signal, through a receiving and transmitting port.

In addition, in the signal reception and output operation S10, the dual-band filter outputs the first band signal through the receiving and transmitting port as a single signal in response to receiving the first band signal.

In addition, in the signal reception and output operation S10, the dual-band filter receives the first band signal within the 2.4 GHz band, amplified by a CMOS power amplifier through the receiving and transmitting port. In the signal reception and output operation S10, the dual-band filter receives and transmits the second band signal within the 5 GHz band through the receiving and transmitting port as the single signal.

In the band selection operation S20, the dual-band filter selects one of the first band signal and the second band signal received and transmitted in the signal reception and output operation S10, to transmit the selected signal to an antenna. In the band selection operation S20, the dual-band filter selects and receive one of the first band signal and the second band signal from the antenna.

In bandpass filtering operation S30, the dual-band filter band-pass filters the first band signal.

In the signal conversion operation S40, the dual-band filter converts the first band signal, a differential signal, to a single signal when the first band signal is transmitted.

In one illustrative example, referring to FIG. 6, a reception process in the operating method of a dual-band filter is performed in the order of the band selection process, the bandpass filtering process, the signal conversion process, and the signal output process.

In one illustrative example, referring to FIG. 7, a transmission process in the operating method of a dual-band filter is performed in the order of the signal reception process, the signal conversion process, the bandpass filtering process, and the band selection process.

As set forth above, according to various embodiments, the communications of the dual-band is supported and energy efficiency at the time of receiving and transmitting a signal is increased.

The apparatuses, filters, balun, network, diplexer, and other components illustrated in FIGS. 1 and 2 that perform the operations described herein with respect to FIGS. 6 and 7 are implemented by hardware components. Examples of hardware components include multiplexers, controllers, sensors, generators, drivers, and any other electronic components known to one of ordinary skill in the art. In one example, the hardware components are implemented by one or more processors or computers. A processor or computer is implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices known to one of ordinary skill in the art that is capable of responding to and executing instructions in a defined manner to achieve a desired result. In one example, a processor or computer includes, or is connected to, one or more memories storing instructions or software that are executed by the processor or computer. Hardware components implemented by a processor or computer execute instructions or software, such as an operating system (OS) and one or more software applications that run on the OS, to perform the operations described herein with respect to FIGS. 6 and 7. The hardware components also access, manipulate, process, create, and store data in response to execution of the instructions or software. For simplicity, the singular term “processor” or “computer” may be used in the description of the examples described herein, but in other examples multiple processors or computers are used, or a processor or computer includes multiple processing elements, or multiple types of processing elements, or both. In one example, a hardware component includes multiple processors, and in another example, a hardware component includes a processor and a controller. A hardware component has any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 6 and 7 that perform the operations described herein with respect to FIGS. 6 and 7 are performed by a processor or a computer as described above executing instructions or software to perform the operations described herein.

It is to be understood that in the embodiment of the present invention, the operations in FIGS. 6 and 7 are performed in the sequence and manner as shown although the order of some operations and the like may be changed without departing from the spirit and scope of the described configurations. In accordance with an illustrative example, a computer program embodied on a non-transitory computer-readable medium may also be provided, encoding instructions to perform at least the method described in FIGS. 6 and 7.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. Programmers of ordinary skill in the art can readily write the instructions or software based on the block diagrams and the flow charts illustrated in the drawings and the corresponding descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any device known to one of ordinary skill in the art that is capable of storing the instructions or software and any associated data, data files, and data structures in a non-transitory manner and providing the instructions or software and any associated data, data files, and data structures to a processor or computer so that the processor or computer can execute the instructions. In one example, the instructions or software and any associated data, data files, and data structures are distributed over network-coupled computer systems so that the instructions and software and any associated data, data files, and data structures are stored, accessed, and executed in a distributed fashion by the processor or computer.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A dual-band filter, comprising:
a diplexer configured to process one of a first band signal and a second band signal, which comprises a frequency band different from a frequency band of the first band signal, and block the other of the first band signal and the second band signal;
a balun configured to
convert the first band signal from a differential signal to a single signal in response to the first band signal being transmitted, and
convert the first band signal from a single signal to a differential signal in response to the first band signal being received; and
a direct current (DC) voltage supply port configured to supply a DC voltage to the balun when the first band signal is received.

2. The dual-band filter of claim 1, further comprising:
a first signal port configured to receive or transmit the first band signal as a differential signal;
a second signal port configured to receive or transmit the second band signal; and
a common port configured to transmit or receive the first band signal or the second band signal to or from an antenna.

3. The dual-band filter of claim 2, wherein the first signal port transmits the first band signal amplified by a complementary metal-oxide semiconductor (CMOS) power amplifier.

4. The dual-band filter of claim 2, wherein the first signal port transmits and receives a first band signal, within the 2.4 GHz band, and
the second signal port transmits and receives a second band signal, within the 5 GHz band, as a single signal.

5. The dual-band filter of claim 1, further comprising:
a bandpass filter configured to filter the first band signal.

6. The dual-band filter of claim 5, wherein the bandpass filter comprises a surface acoustic wave filter or a bulk film acoustic resonator filter.

7. The dual-band filter of claim 2, further comprising:
a first matching network connected between the second signal port and the diplexer;
a second matching network connected between the diplexer and a bandpass filter, wherein the bandpass filter is configured to filter the first band signal; and
a third matching network connected between the bandpass filter and the balun.

8. A dual-band filter, comprising:
a common port configured to receive or transmit a first band signal or a second band signal, wherein the second band signal comprises a frequency band different from a frequency band of the first band signal;
a diplexer configured to process one of the first band signal and the second band signal and to block the other of the first band signal and the second band signal;
a bandpass filter connected to the diplexer and configured to filter the first band signal; and
a balun configured to convert the filtered first band signal from a differential signal to a single signal when the first band signal is transmitted.

9. The dual-band filter of claim 8, further comprising:
a first signal transmitting port configured to receive the first band signal as the differential signal;
a first signal receiving port configured to transmit the first band signal as the single signal; and
a second signal port configured to receive or transmit the second band signal.

10. The dual-band filter of claim 9, wherein the diplexer is connected to the second signal port and the common port, and
the balun is connected to the bandpass filter and the first signal transmitting port.

11. The dual-band filter of claim 9, wherein the first signal receiving port is connected to the bandpass filter to output the first band signal as the single signal.

12. The dual-band filter of claim 9, wherein the first signal transmitting port transmits the first band signal, within the 2.4 GHz band, amplified by a complementary metal-oxide semiconductor (CMOS) power amplifier, and
the second signal port transmits and receives the second band signal, within the 5 GHz band, as the single signal.

13. The dual-band filter of claim 9, further comprising:
a first matching network connected between the second signal port and the diplexer;
a second matching network connected between the diplexer and the bandpass filter; and
a third matching network connected between the bandpass filter and the balun,
wherein the bandpass filter comprises a surface acoustic wave filter or a film bulk acoustic resonator filter.

14. A method of a dual-band filter, comprising:
processing, using a diplexer, one of a first band signal and a second band signal, which comprises a frequency band different from a frequency band of the first band signal, and blocking the other of the first band signal and the second band signal;
converting, using a balun, the first band signal from a differential signal to a single signal in response to the first band signal being transmitted;
converting, using the balun, the first band signal from a single signal to a differential signal in response to the first band signal being received; and
supplying, using a direct current (DC) voltage supply port, a DC voltage to the balun when the first band signal is received.

15. The method of claim 14, further comprising:
receiving or transmitting, using a first signal port, the first band signal as a differential signal;
receiving or transmitting, using a second signal port, the second band signal; and
transmitting or receiving, using a common port, the first band signal or the second band signal to or from an antenna.

16. The method of claim 15, further comprising:
amplifying the first band signal using a complementary metal-oxide semiconductor (CMOS) power amplifier; and
transmitting, using the first signal port, the amplified first band signal.
